(19) United States
(12) Patent Application Publication
(10) Pub. No.: US 2026/0122798 A1
(43) Pub. Date: Apr. 30, 2026

(54) DISPLAY APPARATUS

(71) Applicant: SAMSUNG ELECTRONICS CO., LTD., Suwon-si (KR)

(72) Inventors: Seunggeun Song, Suwon-si (KR); Junpil Oh, Suwon-si (KR); Youngsoon Jang, Suwon-si (KR); Kwon Jeong, Suwon-si (KR); Sunggi Kim, Suwon-si (KR); Euishik Yoon, Suwon-si (KR)

(73) Assignee: SAMSUNG ELECTRONICS CO., LTD., Suwon-si (KR)

(21) Appl. No.: 19/322,128

(22) Filed: Sep. 8, 2025

Related U.S. Application Data
(63) Continuation of application No. PCT/KR2025/013233, filed on Aug. 29, 2025.

(30) Foreign Application Priority Data
Oct. 28, 2024 (KR) 10-2024-0149088

(51) Int. Cl. H05K 5/02; H05K 5/00

(52) U.S. Cl. CPC H05K 5/0217; H05K 5/0086

(57) ABSTRACT

A display apparatus includes a display panel; a rear cover covering a side of the display panel; and a reinforcing member between the display panel and the rear cover and configured to support the display panel, the reinforcing member being formed of a plastic resin and including a plurality of hollows respectively extending in a direction in which the display panel extends.

### CROSS-REFERENCE TO RELATED APPLICATION(S)

This application is a continuation of International Application No. PCT/KR2025/013233, filed on Aug. 29, 2025, in the Korean Intellectual Property Receiving Office, which is based on and claims priority to Korean Patent Application No. 10-2024-0149088, filed on Oct. 28, 2024, in the Korean Intellectual Property Office, the disclosures of which are incorporated by reference herein in their entireties.

### BACKGROUND

### 1. Field

The disclosure relates to a display apparatus including a display panel.

### 2. Description of Related Art

A display panel displays an input image signal as an image on an effective image display surface. Display panels are implemented in various configurations such as liquid crystal panels and plasma panels according to their characteristics, and are applied to various display apparatuses.

Display panels may be classified into a light-receiving panel structure and a self-emissive panel structure based on how light for displaying an image is generated. The light-receiving panel structure may be a non-emissive structure which does not emit light by itself, and thus may require a backlight to generate and supply light to the display panel. For example, a liquid crystal display panel may correspond to the light-receiving panel structure. The self-emissive panel structure may not require a separate backlight because the panel may emit light by itself. For example, an organic light emitting diode (OLED) panel or a light emitting diode (LED) signage may correspond to the self-emissive panel structure.

A display apparatus may include a configuration for reinforcing strength. When the configuration for reinforcing strength includes a metal material, the weight of the display apparatus may increase, and material costs and manufacturing costs may increase.

### SUMMARY

Provided is a display apparatus which may have reduced weight.

Further, provided is a display apparatus that may reduce damage caused by external impact.

Further, provided is a display apparatus which may have improved durability.

Additional aspects will be set forth in part in the description which follows and, in part, will be apparent from the description, or may be learned by practice of the presented embodiments.

According to an aspect of the disclosure, a display apparatus may include: a display panel; a rear cover covering a side of the display panel; and a reinforcing member between the display panel and the rear cover and configured to support the display panel, the reinforcing member being formed of a plastic resin and including a plurality of hollows respectively extending in a direction in which the display panel extends.

The plurality of hollows of the reinforcing member may respectively extend in a horizontal direction.

The reinforcing member may further include a support portion between the plurality of hollows and extending in the direction in which the plurality of hollows extend.

The reinforcing member may be configured to absorb an external force applied to the display panel.

The reinforcing member may be formed by extrusion molding.

The display apparatus may further include: a cover fixing layer configured to fix the reinforcing member to the rear cover.

The cover fixing layer may include a double-sided tape.

The display apparatus may further include: a panel fixing layer configured to fix the reinforcing member to the display panel.

The display apparatus may further include: a source board at a lower part of the display panel and between the display panel and the rear cover, the source board being connected to the display panel, where the reinforcing member extends from an upper part of the source board to an upper end of the display panel and between the display panel and the rear cover.

A thickness of the reinforcing member in a front-back direction may be equal to or greater than a thickness of the source board in the front-back direction.

The display apparatus may further include: a board bracket behind the reinforcing member; and a printed circuit board on the board bracket, where the reinforcing member includes a through-hole for a cable of the printed circuit board.

The display apparatus may further include: a board cover detachably mounted to the rear cover and covering the printed circuit board.

The printed circuit board may include at least one of a main board, a timing controller, or a communicator.

The display apparatus may further include: a battery detachably mounted to the rear cover.

The display apparatus may further include: a battery cover detachably mounted to the rear cover and covering the battery.

According to an aspect of the disclosure, a display apparatus may include: a display panel; a rear cover covering a side of the display panel; and a plastic reinforcing member between the display panel and the rear cover and configured to support the display panel, the plastic reinforcing member including a plurality of hollows respectively extending in a direction in which the display panel extends.

The plastic reinforcing member may further include a support portion between the plurality of hollows and extending in the direction in which the plurality of hollows extend, wherein the plastic reinforcing member is configured to absorb an external force applied to the display panel.

The display apparatus may further include: a source board at a lower part of the display panel and between the display panel and the rear cover, the source board being connected to the display panel, where the plastic reinforcing member extends from an upper part of the source board to an upper end of the display panel and between the display panel and the rear cover.

The display apparatus may further include: a board bracket behind the plastic reinforcing member; and a printed circuit board on the board bracket, where the plastic reinforcing member includes a through-hole for a cable of the printed circuit board.

The display apparatus may further include: a board cover detachably mounted to the rear cover and covering the printed circuit board.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates a display apparatus according to an embodiment of the disclosure;

FIG. 2 is an exploded view of some components of a display apparatus according to an embodiment of the disclosure;

FIG. 3 is an exploded view of some components of a display apparatus when viewed from a different direction in FIG. 2 according to an embodiment of the disclosure;

FIG. 4 is an enlarged view of a portion A shown in FIG. 3 according to an embodiment of the disclosure;

FIG. 5 illustrates a portion of a cross-section taken along line B-B′ shown in FIG. 1 according to an embodiment of the disclosure;

FIG. 6 is a partial cross-sectional view of a display apparatus according to an embodiment of the disclosure;

FIG. 7 illustrates mounting a reinforcing member of a display apparatus to a rear cover according to an embodiment of the disclosure;

FIG. 8 illustrates a state in which a reinforcing member of a display apparatus is mounted to a rear cover according to an embodiment of the disclosure;

FIG. 9 illustrates mounting a display panel to a reinforcing member mounted to a rear cover of a display apparatus according to an embodiment of the disclosure; and

FIG. 10 illustrates mounting a display panel to a reinforcing member of a display apparatus according to an embodiment of the disclosure.

### DETAILED DESCRIPTION

Various embodiments and the terms used herein are not intended to limit the technology disclosed herein to specific forms, and the disclosure should be understood to include various modifications, equivalents, and/or alternatives to the corresponding embodiments.

In addition, in describing the drawings, similar reference numerals may be used to designate similar constituent elements.

In addition, the singular form of a noun corresponding to an item may include one or more of the items unless clearly indicated otherwise in a related context.

In addition, the phrases, “such as “A or B”, “at least one of A and B”, “at least one of A or B”, “A, B or C”, “at least one of A, B and C”, and “at least one of A, B, or C” may include any one or all possible combinations of the items listed together in the corresponding phrase among the phrases.

In addition, terms such as “portion”, “module”, and “member” may be embodied as hardware or software. According to embodiments, a plurality of “portions”, “modules”, and “members” may be implemented as a single component or a single “portion”, “module”, and “member” may include a plurality of components.

In addition, the terms used herein are used only to describe particular embodiments and are not intended to limit the disclosure. It is to be understood that the singular forms are intended to include the plural forms as well, unless the context clearly dictates otherwise. It will be understood that the terms “comprise,” “include,” “have,” and the like, are intended to indicate the presence of the features, numbers, steps, operations, components, parts, or combinations thereof disclosed in the disclosure, but do not preclude the presence or addition of one or more other elements.

In addition, it will be understood that, although the terms including ordinal numbers, such as “first”, “second”, etc., may be used herein to describe various components, these components should not be limited by these terms. These terms are only used to distinguish one component from another. For example, a first component could be termed a second component, and, similarly, a second component could be termed a first component, without departing from the scope of the disclosure. As used herein, the term “and/or” includes any and all combinations of one or more of associated listed items.

When an element (e.g., a first element) is referred to as being “(functionally or communicatively) coupled,” or “connected” to another element (e.g., a second element), the first element may be connected to the second element, directly (e.g., wired), wirelessly, or through a third element.

When an element is said to be “connected”, “coupled”, “supported” or “contacted” with another element, this includes not only when elements are directly connected, coupled, supported or contacted, but also when elements are indirectly connected, coupled, supported or contacted through a third element.

When an element is “on” another element, this includes not only when the element is in contact with the other element, but also when there is another element between the two elements.

Terms such as “up-down direction,” “front-back direction,” etc., used in the following description are defined based on the drawings, and the shapes and positions of each component are not limited by these terms. For example, hereinafter, the X direction may include the front-back direction, the Y direction may include the left-right direction, and the Z direction may include the up-down direction.

In the disclosure, a flat display apparatus is described as an example, but the configuration of the disclosure may also be applied to a curved display apparatus or a bendable or flexible display apparatus in which a flat state and a curved state are variable. In addition, the configuration of the disclosure may be applied to all display apparatuses regardless of the screen size of the display apparatus.

Hereinafter, embodiments according to the disclosure will be described in detail with reference to the accompanying drawings.

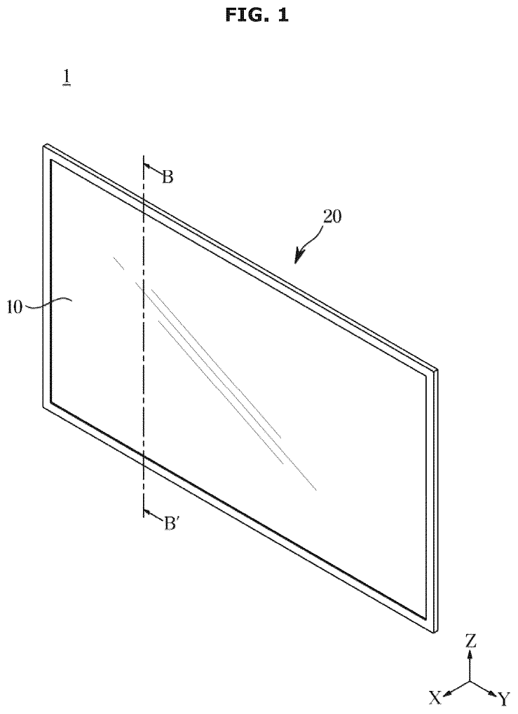

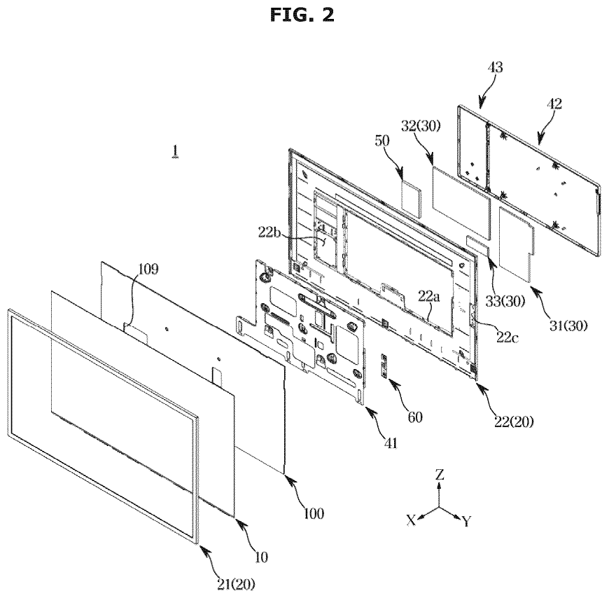

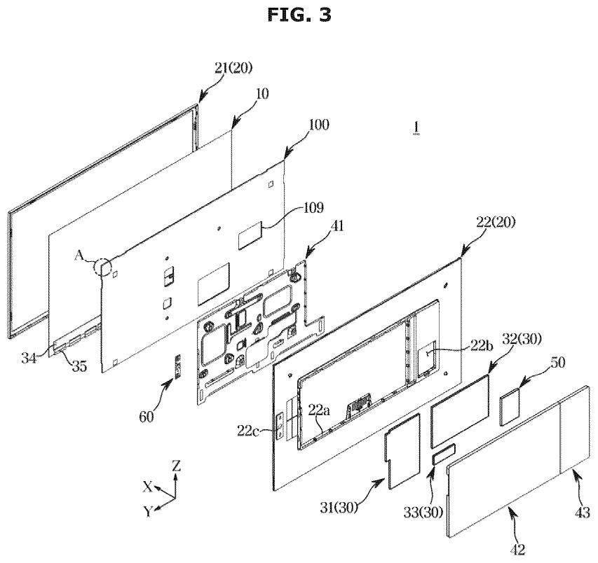

FIG. 1 illustrates a display apparatus according to an embodiment of the disclosure. FIG. 2 is an exploded view of some components of a display apparatus according to an embodiment of the disclosure. FIG. 3 is an exploded view of some components of a display apparatus when viewed from a different direction in FIG. 2.

Referring to FIG. 1 to FIG. 3, a display apparatus 1 according to an embodiment of the disclosure may be an apparatus capable of processing an image signal received from the outside and visually displaying the processed image. In the disclosure, a case where the display apparatus 1 is a signage is described as an example, but is not limited thereto. For example, the display apparatus 1 may be implemented in various forms, such as a television (TV), a monitor, a portable multimedia apparatus, a portable communication apparatus, etc., and the form of the display apparatus 1 is not limited as long as it is an apparatus that visually displays an image.

In addition, the display apparatus 1 may be a large format display (LFD) installed outdoors, such as on a building rooftop or at a bus stop. Here, the outdoors is not limited to open-air spaces, and the display apparatus 1 according to an embodiment of the disclosure may be installed in any place where many people may come and go, such as a subway station, a shopping mall, a movie theater, an office, or a store, although the place is an indoor space.

The display apparatus 1 may receive content including a video signal and an audio signal from various content sources, and may output video and audio corresponding to the video signal and the audio signal. For example, the display apparatus 1 may receive content data through a broadcasting reception antenna or a wired cable, receive content data from a content reproducing apparatus, or receive content data from a content providing server of a content provider.

The display apparatus 1 may be configured to display a screen. For example, the display apparatus 1 may include a display panel 10 that displays an image on the front.

A plurality of pixels are formed on the display panel 10, and a screen displayed on the display panel 10 may be formed by a combination of light emitted from the plurality of pixels. For example, the light emitted from the plurality of pixels may be combined like a mosaic to form one screen.

Each of the plurality of pixels may emit light of various brightnesses and various colors. For example, each of the plurality of pixels may include sub-pixels, and the sub-pixels may include a red sub-pixel capable of emitting red light, a green sub-pixel capable of emitting green light, and a blue sub-pixel capable of emitting blue light. Each of the plurality of pixels may emit light of various brightnesses and various colors by a combination of light emitted from the red sub-pixel, the green sub-pixel, and the blue sub-pixel, respectively.

The display panel 10 may include an electronic paper display, an organic light-emitting diode (OLED), and a liquid crystal display (LCD). The type of the display panel 10 is not limited, and the display apparatus 1 may include various types of the display panel 10.

For example, the display panel 10 may include electronic paper that forms a screen with an arrangement of color particles, as a reflective display that does not require a backlight. In a case where the display panel 10 includes electronic paper, the display apparatus 1 may not include a light source and/or optical materials. In a case where the display panel 10 includes electronic paper, the display apparatus 1 may maintain the screen even when the power supply is interrupted, and thus, mobility may be improved.

For example, the display panel 10 may be a self-emissive display panel such as an OLED panel.

In a case where the display panel 10 is an LCD panel, the display panel 10 may include a thin film transistor (TFT) substrate on which thin film transistors are formed in a matrix form, a color filter substrate coupled in parallel with the TFT substrate, and a liquid crystal injected between the TFT substrate and the color filter substrate, whose optical properties are variable depending on changes in voltage or temperature.

The display apparatus 1 may include a case 20 that supports the display panel 10. The case 20 may support a front surface, side surfaces, or rear surface of the display panel 10.

The case 20 may form the external appearance of the display apparatus 1, and various components for the display apparatus 1 to display an image or perform various functions may be provided in the case 20. Although the case 20 is shown as a flat plate shape in FIG. 1 to FIG. 3, the shape of the case 20 is not limited thereto. For example, the case 20 may have a curved plate shape that corresponds to that of the display panel 10. According to an embodiment, the case 20 may be configured to vary between a flat state and a curved state, and may be applied to a bendable or flexible display apparatus 1.

The case 20 may include a front chassis 21 that supports the front surface to the side surfaces of the display panel 10. The front chassis 21 may form a bezel disposed to face the front of the display apparatus 1 to support the front surface of the display panel 10. However, in a case where the display apparatus 1 is a bezel-less type display apparatus with a very narrow or no bezel, the front chassis 21 may be provided to support only the side surfaces of the display panel 10. Furthermore, when a rear cover 22 supports the side surfaces of the display panel 10, the display apparatus 1 may not include the front chassis 21.

The case 20 may include the rear cover 22 that supports the rear of the display panel 10. The rear cover 22 may cover at least a portion of the rear of the display panel 10. In a case where the display apparatus 1 includes the front chassis 21, the rear cover 22 may be coupled to the rear of the front chassis 21. The rear cover 22 may form at least a portion of the rear surface of the display apparatus 1.

The rear cover 22 may include a cover opening 22a that forms a space for a printed circuit board (PCB, 30) to be located. The cover opening 22a may penetrate the rear cover 22 and have a hole shape. As the PCB 30 is located in the space formed by the cover opening 22a, the thickness of the display apparatus 1 may be reduced.

The rear cover 22 may include a battery mounting portion 22b for mounting a battery 50. The battery mounting portion 22b may be located on one side of the cover opening 22a. For example, the battery mounting portion 22b may be in the form of a groove on the rear surface of the rear cover 22.

The rear cover 22 may include an input mounting portion 22c for mounting an input portion 60. The input mounting portion 22c may be located on one side of the cover opening 22a. For example, the input mounting portion 22c may be located on one edge of the rear cover 22. The input mounting portion 22c may expose part of the input portion 60 to allow a user to operate the input portion 60.

The display apparatus 1 may include a board bracket 41 for mounting the PCB 30. The board bracket 41 may be mounted to the rear cover 22. The board bracket 41 may be mounted in the cover opening 22a of the rear cover 22. For example, the board bracket 41 may have a shape and/or size similar to the shape and/or size of the cover opening 22a of the rear cover 22. When the board bracket 41 is mounted to the rear cover 22, the board bracket 41 may be accommodated in the cover opening 22a.

The display apparatus 1 may include a board cover 42. The board cover 42 may cover the cover opening 22a formed in the rear cover 22. The board cover 42 may be detachably mounted to the rear cover 22. The board cover 42 may cover at least a portion of the PCB 30 located in the cover opening 22a.

The display apparatus 1 may include a battery cover 43. The battery cover 43 may cover the battery mounting portion 22b formed in the rear cover 22. The battery cover 43 may be detachably mounted to the rear cover 22. The battery cover 43 may cover the battery 50 located in the battery mounting portion 22b.

The display apparatus 1 may include the PCB 30. The PCB 30 may be accommodated in the rear cover 22. The PCB 30 may be located in the space formed by the cover opening 22a of the rear cover 22. The PCB 30 may be mounted to the board bracket 41. For example, the PCB 30 may be mounted on the rear surface of the board bracket 41. The PCB 30 may be disposed between the board bracket 41 and the board cover 42. However, the disclosure is not limited thereto, and the PCB 30 may be disposed at various locations of the case 20.

The PCB 30 may be formed by printing a circuit line pattern using a conductive material such as copper on an electrically insulating substrate. The circuit line pattern on the PCB 30 and the electronic components mounted on the PCB 30 may vary depending on the functions provided by the display apparatus 1. Various types of PCBs 30 may be provided depending on the functions or configurations of the display apparatus 1.

For example, the PCB 30 may include a main board 31. The main board 31 may include a processor and a power management device for driving the display apparatus 1.

For example, the PCB 30 may include a timing controller 32. The timing controller 32 may generate a timing signal required for controlling the display apparatus 1.

For example, the PCB 30 may include a communicator 33. The communicator 33 may allow the display apparatus 1 to transmit information to an external device and receive information from the external device.

For example, the PCB 30 may include a source board 34. The source board 34 may control the display panel 10 of the display apparatus 1. For example, the source board 34 may process digital image data and output an analog image signal.

The display apparatus 1 may include a cable 35 that connects the source board 34 to the display panel 10. The cable 35 may transmit image data to the display panel 10. For example, the cable 35 may include a flexible printed circuit board (FPCB).

For example, the source board 34 may be located at the lower end of the display panel 10, and the cable 35 may be bent and extended from the source board 34 along the lower edge of the display panel 10 and be connected to the display panel 10.

Referring to FIG. 2, although the plurality of PCBs 30, such as the main board 31, the timing controller 32, the communicator 33, and the source board 34, are shown as being independently disposed, the disclosure is not limited thereto. At least some configurations of the plurality of PCBs 30 may be mutually merged and disposed. The independently disposed PCBs 30 may be electrically connected to each other to exchange data, signals, or power.

As shown in FIG. 2, a plurality of the PCBs 30 may be provided, and each of the plurality of PCBs 30 may be configured with the main board 31, the timing controller 32, the communicator 33, the source board 34, and the like. The plurality of PCBs 30 may be electrically connected to each other to perform functions for driving the display apparatus 1. In some examples, the PCB 30 may be integrated with each other to perform functions.

The display apparatus 1 may include the battery 50. The battery 50 may supply power for driving the display apparatus 1. The battery 50 may be rechargeable.

The display apparatus 1 may include a reinforcing member 100 to reinforce the strength of the display apparatus 1. The reinforcing member 100 may be located between the display panel 10 and the rear cover 22. The reinforcing member 100 may be located behind the display panel 10. The reinforcing member 100 may be located in front of the board bracket 41. The reinforcing member 100 may support the display panel 10. The reinforcing member 100 may have a size and/or shape corresponding to the size and/or shape of the display panel 10.

In the display apparatus 1 according to an embodiment, the reinforcing member 100 may support the display panel 10, thereby reducing sagging of the display panel 10 to the rear.

The reinforcing member 100 may include a material lighter than metal. For example, the reinforcing member 100 may include a plastic resin. For example, the reinforcing member 100 may include polypropylene (PP). The reinforcing member 100 may include a material lighter than the case 20. The reinforcing member 100 may include a material lighter than the rear cover 22.

In the display apparatus 1, according to an embodiment, the reinforcing member 100 may include a material lighter than metal, thereby reducing the weight of the display apparatus 1, compared to a display apparatus including a metal reinforcing member.

The reinforcing member 100 may include a through-hole 109 for a cable or the like to pass through. For example, a cable for connecting the PCB 30 and the display panel 10 may pass through the through-hole 109. For example, at least one or more of the through-hole 109 may be provided.

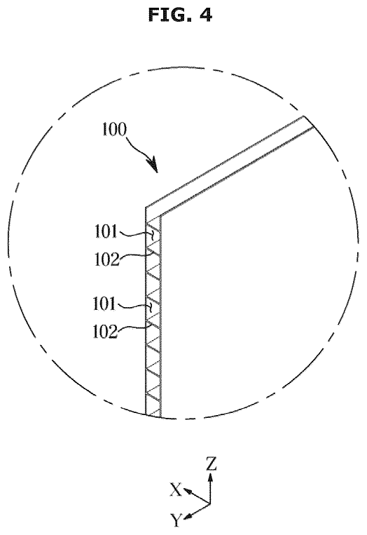

FIG. 4 is an enlarged view of a portion A shown in FIG. 3.

Referring to FIG. 3 and FIG. 4, the reinforcing member 100 may include a hollow 101 formed therein. For example, the hollow 101 may extend in the length direction of the reinforcing member 100. For example, the hollow 101 may extend in the left-right direction. A plurality of the hollows 101 may be provided. The hollow 101 may extend in the direction in which the display panel 10 extends. The hollow 101 may extend in the horizontal direction.

The reinforcing member 100 may include a support portion 102 positioned between the plurality of hollows 101. For example, the support portion 102 may extend in the length direction of the reinforcing member 100. For example, the support portion 102 may extend in the left-right direction. The support portion 102 may extend in the direction in which the plurality of hollows 101 extend. The support portion 102 may extend in the horizontal direction. A plurality of the support portions 102 may be provided.

In the display apparatus 1 according to an embodiment, because the reinforcing member 100 includes the hollow 101, the weight of the display apparatus 1 may be reduced. In the display apparatus 1 according to an embodiment, the reinforcing member 100 may include the hollow 101, thereby cushioning the impact applied to the display panel 10 and reducing damage to the display panel 10. According to an embodiment, when an external force is applied to the display panel 10, the reinforcing member 100 may absorb at least part of the external force applied to the display panel 10.

In the display apparatus 1 according to an embodiment, because the hollow 101 and the support portion 102 of the reinforcing member 100 extend in the left-right direction of the display apparatus 1, bending of the display apparatus 1 may be reduced, and the strength may be improved.

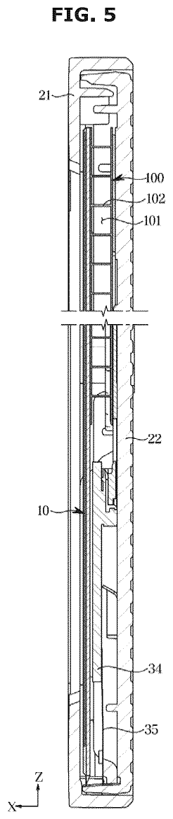

FIG. 5 illustrates a portion of a cross-section taken along line B-B′ shown in FIG. 1.

Referring to FIG. 3 and FIG. 5, the reinforcing member 100 may be disposed between the display panel 10 and the rear cover 22. The reinforcing member 100 may extend in the up-down direction. For example, the source board 34 may be located at the lower end of the display panel 10, and the reinforcing member 100 may extend from the upper part of the source board 34 to the upper end of the display panel.

For example, the reinforcing member 100 may be provided with a thickness corresponding to the thickness of the source board 34. The reinforcing member 100 may be disposed in the space between the display panel 10 and the rear cover 22 generated by the source board 34. Because the reinforcing member 100 has a thickness corresponding to the thickness of the source board 34 and is disposed in the space between the display panel 10 and the rear cover 22 generated by the source board 34, an increase in the thickness of the display apparatus 1 may be prevented.

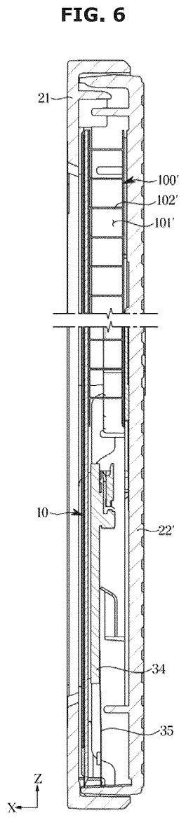

FIG. 6 is a partial cross-sectional view of a display apparatus according to an embodiment of the disclosure.

In describing a reinforcing member 100′ according to an embodiment with reference to FIG. 6, the same reference numerals are used for the same components as in FIG. 5, and detailed descriptions thereof may be omitted.

Referring to FIG. 6, the reinforcing member 100′ may be disposed between the display panel 10 and a rear cover 22′. The reinforcing member 100′ may extend in the up-down direction. For example, the source board 34 may be located at the lower end of the display panel 10, and the reinforcing member 100′ may extend from the upper part of the source board 34 to the upper end of the display panel.

For example, the reinforcing member 100′ may be provided with a thickness greater than the thickness of the source board 34. The thickness of the reinforcing member 100′ may be greater than that of the reinforcing member 100 shown in FIG. 5. Because the thickness of the reinforcing member 100′ is greater than that of the source board 34, the rear cover 22′ may be spaced apart from the source board 34. Because the thickness of the reinforcing member 100′ is greater than that of the source board 34, the thickness of the rear cover 22′ may be increased to cover the reinforcing member 100′, compared to the rear cover 22 shown in FIG. 5. As the reinforcing member 100′ is provided with a thickness greater than the thickness of the source board 34, the strength of the display apparatus 1 may be improved.

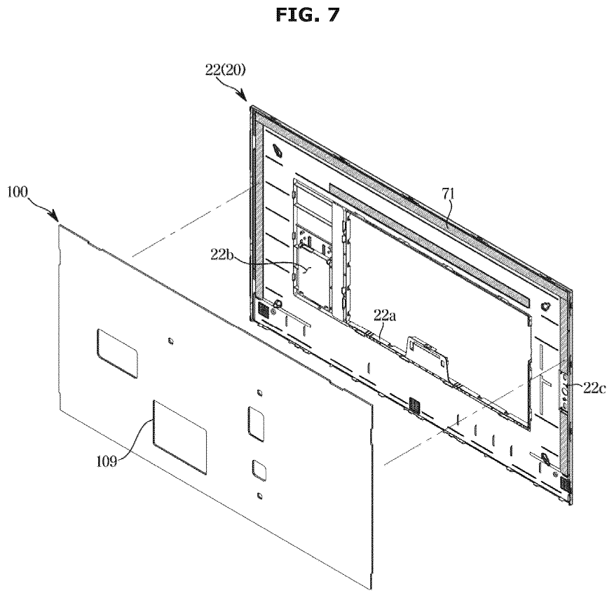

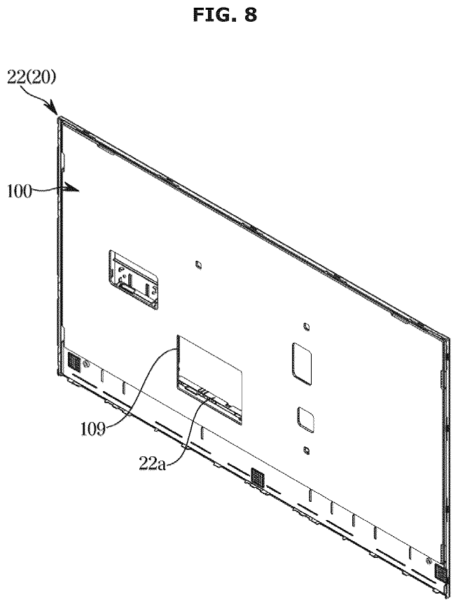

FIG. 7 illustrates mounting a reinforcing member of a display apparatus to a rear cover according to an embodiment of the disclosure. FIG. 8 illustrates a state in which a reinforcing member of a display apparatus is mounted to a rear cover according to an embodiment of the disclosure.

Referring to FIG. 7 and FIG. 8, the display apparatus 1 according to an embodiment may include a cover fixing layer 71 for fixing the reinforcing member 100 to the rear cover 22. For example, the reinforcing member 100 may be manufactured by an extrusion molding process, and thus forming a structure for mounting to the rear cover 22 may not be easy.

The cover fixing layer 71 may be provided along at least one edge of the rear cover 22. For example, the cover fixing layer 71 may be provided on the upper edge and the left and right side edges of the rear cover 22, but is not limited thereto. The cover fixing layer 71 may be provided at the lower part of the rear cover 22, or on at least one edge of the reinforcing member 100. The cover fixing layer 71 may be provided on the front surface of the rear cover 22.

For example, the cover fixing layer 71 may include a double-sided tape, but is not limited thereto. The cover fixing layer 71 may include an adhesive or the like.

In a state where the reinforcing member 100 is fixed to the rear cover 22 by the cover fixing layer 71, the reinforcing member 100 may be accommodated inside the case 20 as the front chassis 21 is mounted to the rear cover 22.

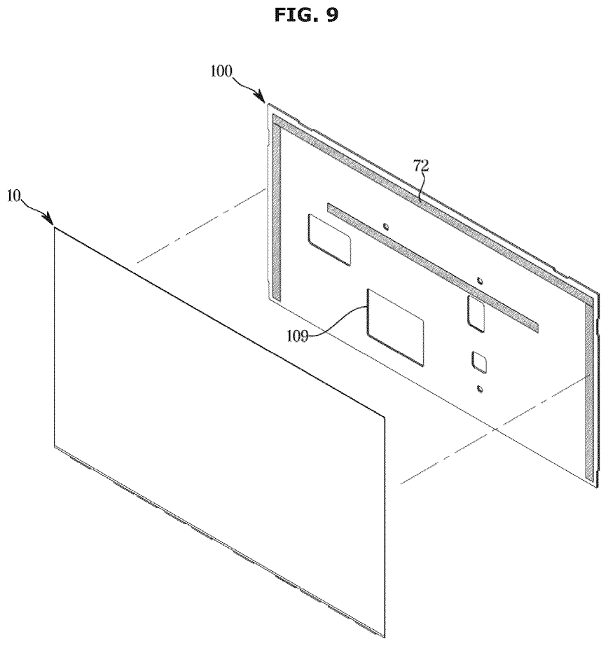

FIG. 9 illustrates mounting a display panel to a reinforcing member mounted to a rear cover of a display apparatus according to an embodiment of the disclosure.

Referring to FIG. 9, the display apparatus 1 according to an embodiment may further include a panel fixing layer 72 for fixing the display panel 10 to the reinforcing member 100. For example, the reinforcing member 100 may be manufactured by an extrusion molding process, and thus forming a structure for mounting to the display panel 10 may not be easy.

The panel fixing layer 72 may be provided along at least one edge of the reinforcing member 100. For example, the panel fixing layer 72 may be provided on the upper edge and the left and right side edges of the reinforcing member 100, but is not limited thereto. The panel fixing layer 72 may be provided at the lower part of the reinforcing member 100, or on at least one edge of the display panel 10. The panel fixing layer 72 may be provided on the front surface of the reinforcing member 100.

For example, the panel fixing layer 72 may include a double-sided tape, but is not limited thereto. The panel fixing layer 72 may include an adhesive or the like.

In a state where the reinforcing member 100 is fixed to the display panel 10 by the panel fixing layer 72, the reinforcing member 100 may be received between the front chassis 21 and the rear cover 22.

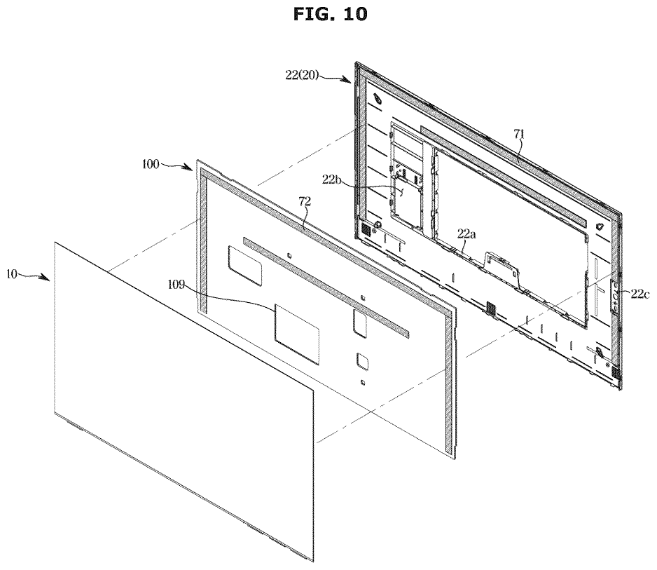

FIG. 10 illustrates mounting a display panel to a reinforcing member of a display apparatus according to an embodiment of the disclosure.

Referring to FIG. 10, the display apparatus 1 according to an embodiment may include both the cover fixing layer 71 and the panel fixing layer 72.

The cover fixing layer 71 shown in FIG. 10 may be provided in the same manner as the cover fixing layer 71 shown in FIG. 7. The panel fixing layer 72 shown in FIG. 10 may be provided in the same manner as the panel fixing layer 72 shown in FIG. 9.

Referring to FIG. 10, in a state where the reinforcing member 100 is fixed to the rear cover 22 by the cover fixing layer 71 and fixed to the display panel 10 by the panel fixing layer 72, the reinforcing member 100 may be accommodated in the case 20 as the front chassis 21 is mounted to the rear cover 22.

Because the front surface of the reinforcing member 100 is fixed to the display panel 10 by the panel fixing layer 72 and the rear surface of the reinforcing member 100 is fixed to the rear cover 22 by the cover fixing layer 71, the rigidity of the display panel 1 according to various embodiments may be improved.

According to an embodiment of the disclosure, a display apparatus may include a display panel, a rear cover covering a side of the display panel, and a reinforcing member between the display panel and the rear cover and configured to support the display panel, the reinforcing member being formed of a plastic resin and including a plurality of hollows respectively extending in a direction in which the display panel extends.

The plurality of hollows of the reinforcing member may respectively extend in a horizontal direction.

The reinforcing member may further include a support portion between the plurality of hollows and extending in the direction in which the plurality of hollows extend.

The reinforcing member may be configured to absorb an external force applied to the display panel.

The reinforcing member may be formed by extrusion molding.

The display apparatus may further include a cover fixing layer configured to fix the reinforcing member to the rear cover.

The cover fixing layer may include a double-sided tape.

The display apparatus may further include a panel fixing layer configured to fix the reinforcing member to the display panel.

The display apparatus may further include a source board at a lower part of the display panel and between the display panel and the rear cover, the source board being connected to the display panel. The reinforcing member may extend from an upper part of the source board to an upper end of the display panel and between the display panel and the rear cover.

A thickness of the reinforcing member in a front-back direction may be equal to or greater than a thickness of the source board in the front-back direction.

The display apparatus may further include a board bracket behind the reinforcing member; and a printed circuit board on the board bracket. The reinforcing member may include a through hole for a cable of the printed circuit board.

The display apparatus may further include a board cover detachably mounted to the rear cover and covering the printed circuit board.

The printed circuit board may include at least one of a main board, a timing controller, or a communicator.

The display apparatus may further include a battery detachably mounted to the rear cover.

The display apparatus may further include a battery cover detachably mounted to the rear cover and covering the battery.

According to an embodiment of the disclosure, a display apparatus may include: a display panel; a rear cover configured to cover a side of the display panel; and a reinforcing member configured to support the display panel between the display panel and the rear cover and including a lighter material than the rear cover. The reinforcing member may include a plurality of hollows formed in a direction in which the display panel extends, and a support portion extending in a direction in which the plurality of hollows extend between the plurality of hollows.

The hollow and the support portion may extend in a horizontal direction.

The reinforcing member may include a plastic resin.

The display apparatus may further include a cover fixing layer configured to fix the reinforcing member to the rear cover.

The display apparatus may further include a source board connected to the display panel and positioned at a lower part of the display panel between the display panel and the rear cover. The reinforcing member may extend from an upper part of the source board to an upper end of the display panel between the display panel and the rear cover, and may have a thickness corresponding to a thickness of the source board.

According to the disclosure, a reinforcing member of a display apparatus may include a plastic resin that is lighter than metal, thereby reducing a weight of the display apparatus.

According to the disclosure, a reinforcing member of a display apparatus may include a plurality of hollows, thereby reducing a weight of the display apparatus.

According to the disclosure, a display apparatus may be provided with a reinforcing member to support a display panel, thereby reducing sagging of the display panel to the rear.

According to the disclosure, a reinforcing member of a display apparatus may include a plurality of hollows, thereby cushioning the impact applied to a display panel and reducing damage to the display panel.

The effects that may achieved by the disclosure are not limited to the above-mentioned effects, and other effects not mentioned will be clearly understood by one of ordinary skill in the technical art to which the disclosure belongs.

Although embodiments of the disclosure have been described with reference to the accompanying drawings, a person having ordinary skilled in the art will appreciate that other specific modifications may be easily made without departing from the technical spirit or essential features of the disclosure. Therefore, the foregoing embodiments should be regarded as illustrative rather than limiting in all aspects, and the scope of various embodiments of the disclosure should be interpreted as encompassing all modifications or variations derived based on the technical spirit of various embodiments of the disclosure in addition to the embodiments disclosed herein.

What is claimed is:

1. A display apparatus comprising:
a display panel;
a rear cover covering a side of the display panel; and
a reinforcing member between the display panel and the rear cover and configured to support the display panel, the reinforcing member being formed of a plastic resin and comprising a plurality of hollows respectively extending in a direction in which the display panel extends.

2. The display apparatus of claim 1, wherein the plurality of hollows of the reinforcing member respectively extend in a horizontal direction.

3. The display apparatus of claim 1, wherein the reinforcing member further comprises a support portion between the plurality of hollows and extending in the direction in which the plurality of hollows extend.

4. The display apparatus of claim 1, wherein the reinforcing member is configured to absorb an external force applied to the display panel.

5. The display apparatus of claim 1, wherein the reinforcing member is formed by extrusion molding.

6. The display apparatus of claim 1, further comprising:
a cover fixing layer configured to fix the reinforcing member to the rear cover.

7. The display apparatus of claim 6, wherein the cover fixing layer comprises a double-sided tape.

8. The display apparatus of claim 1, further comprising:
a panel fixing layer configured to fix the reinforcing member to the display panel.

9. The display apparatus of claim 1, further comprising:
a source board at a lower part of the display panel and between the display panel and the rear cover, the source board being connected to the display panel,
wherein the reinforcing member extends from an upper part of the source board to an upper end of the display panel and between the display panel and the rear cover.

10. The display apparatus of claim 9, wherein a thickness of the reinforcing member in a front-back direction is equal to or greater than a thickness of the source board in the front-back direction.

11. The display apparatus of claim 1, further comprising:
a board bracket behind the reinforcing member; and
a printed circuit board on the board bracket,
wherein the reinforcing member comprises a through-hole for a cable of the printed circuit board.

12. The display apparatus of claim 11, further comprising:
a board cover detachably mounted to the rear cover and covering the printed circuit board.

13. The display apparatus of claim 11, wherein the printed circuit board comprises at least one of a main board, a timing controller, or a communicator.

14. The display apparatus of claim 1, further comprising:
a battery detachably mounted to the rear cover.

15. The display apparatus of claim 14, further comprising:
a battery cover detachably mounted to the rear cover and covering the battery.

16. A display apparatus comprising:
a display panel;
a rear cover covering a side of the display panel; and
a plastic reinforcing member between the display panel and the rear cover and configured to support the display panel, the plastic reinforcing member comprising a plurality of hollows respectively extending in a direction in which the display panel extends.

17. The display apparatus of claim 16, wherein the plastic reinforcing member further comprises a support portion between the plurality of hollows and extending in the direction in which the plurality of hollows extend, and
wherein the plastic reinforcing member is configured to absorb an external force applied to the display panel.

18. The display apparatus of claim 17, further comprising:
a source board at a lower part of the display panel and between the display panel and the rear cover, the source board being connected to the display panel,
wherein the plastic reinforcing member extends from an upper part of the source board to an upper end of the display panel and between the display panel and the rear cover.

19. The display apparatus of claim 18, further comprising:
a board bracket behind the plastic reinforcing member; and
a printed circuit board on the board bracket,
wherein the plastic reinforcing member comprises a through-hole for a cable of the printed circuit board.

20. The display apparatus of claim 19, further comprising:
a board cover detachably mounted to the rear cover and covering the printed circuit board.
